(19) United States
(12) Patent Application Publication
(10) Pub. No.: US 2013/0329491 A1
(43) Pub. Date: Dec. 12, 2013

(54) Hybrid Memory Module

(71) Applicants: Jichuan Chang, Sunnyvale, CA (US); Doe Hyun Yoon, San Jose, CA (US); Parthasarathy Ranganathan, San Jose, CA (US)

(72) Inventors: Jichuan Chang, Sunnyvale, CA (US); Doe Hyun Yoon, San Jose, CA (US); Parthasarathy Ranganathan, San Jose, CA (US)

(21) Appl. No.: 13/494,761

(22) Filed: Jun. 12, 2012

(51) Int. Cl. G11C 7/10; G11C 11/00; G11C 16/04

(52) U.S. Cl. 365/185.03; 365/185.11; 365/185.18; 365/158; 365/163; 365/189.05

(57) ABSTRACT

A hybrid. memory module. The module includes at least two heterogeneous memory devices and a memory buffer in communication with the memory devices to read data from any one of the memory devices and write the data to any other of the memory devices.

### STATEMENT OF GOVERNMENT INTEREST

This invention has been made with Government support under Contract No. DE-SC0005026, awarded by The Department of Energy. The Government has certain rights in the invention.

### BACKGROUND

Modem computers can use one or more of several different kinds of memory elements. One such memory element is dynamic^{.}random-access memory (DRAM), which offers the advantage of great speed but at the cost of frequent refreshing. Also, DRAM is volatile—that is, it loses any data when power is removed. Various kinds of non-volatile memory (NVM) have been developed to avoid the disadvantages of DRAM. NVM includes phase-change memory (PCM), memristors, magnetoresistive RAM (MRAM), spin-transfer torque RAM (STT-RAM), flash memory, and other memory cells that retain stored data when power is removed. Several kinds of NVM devices can be implemented either as single-level cells (SLC) which store a single bit or multi-level cells (MLC) which store more than one bit. Each of these various kinds of memory has strengths and weaknesses, and no one memory device provides an ideal solution for all applications. The differing performance, power, and reliability characteristics of these various heterogeneous memory devices can complement each other and, when combined, can provide a hybrid memory system that is large, fast, and useable. One way to construct such a hybrid memory system is to use a plurality of memory modules each of which contains only one kind of memory device. It is also possible to mix different kinds of memory devices in one module with suitable interfacing.

### BRIEF DESCRIPTION OF THE DRAWINGS

The figures are not drawn to scale. They illustrate the disclosure by examples.

FIG. 1 is a block diagram of an example of a hybrid memory module.

FIG. 2 is a block diagram of an example of a hybrid memory system.

FIG. 3 is a flowchart illustrating an example of a method of controlling a hybrid memory system.

### DETAILED DESCRIPTION

Illustrative examples and details are used in the drawings and in this description, but other configurations may exist and may suggest themselves. Terms of orientation such as up, down, top, and bottom are used only for convenience to indicate spatial relationships of components with respect to each other, and except as otherwise indicated, orientation with respect to external axes is not critical. For clarity, some known methods and structures, have not been described in detail. Methods defined by the claims may comprise steps in addition to those listed, and except as indicated in the claims themselves the steps may be performed in another order than that given. Accordingly, the only limitations are imposed by the claims, not by the drawings or this description.

The systems and methods described herein may be implemented in various forms of hardware, software, firmware, special purpose processors, or a combination thereof. At least a portion thereof may be implemented as an application comprising program instructions that are tangibly embodied on one or more program storage devices such as hard disks, magnetic floppy disks, RAM, ROM, and CDROM, and executable by any device or machine comprising suitable architecture. Some or all of the instructions may be remotely stored and accessed through a communication facility; in one example, execution of remotely-accessed instructions may be referred to as cloud computing. Some of the constituent system components and process steps may be implemented in software, and therefore the connections between system modules or the logic flow of method steps may differ depending on the manner in which they are programmed.

A hybrid memory system having several memory modules each with one kind of memory can consume significant memory channel bandwidth when migrating data from one device to another (for example between flash and DRAM) because the data must be first copied into a central memory controller and then moved into the target device. To combine different kinds of memory devices into a single module has required non-standard interfaces or other complex implementations. Accordingly there has been a need for a way to realize the advantages of combining more than one kind of memory in a single memory system without adversely impacting system performance or raising cost and complexity.

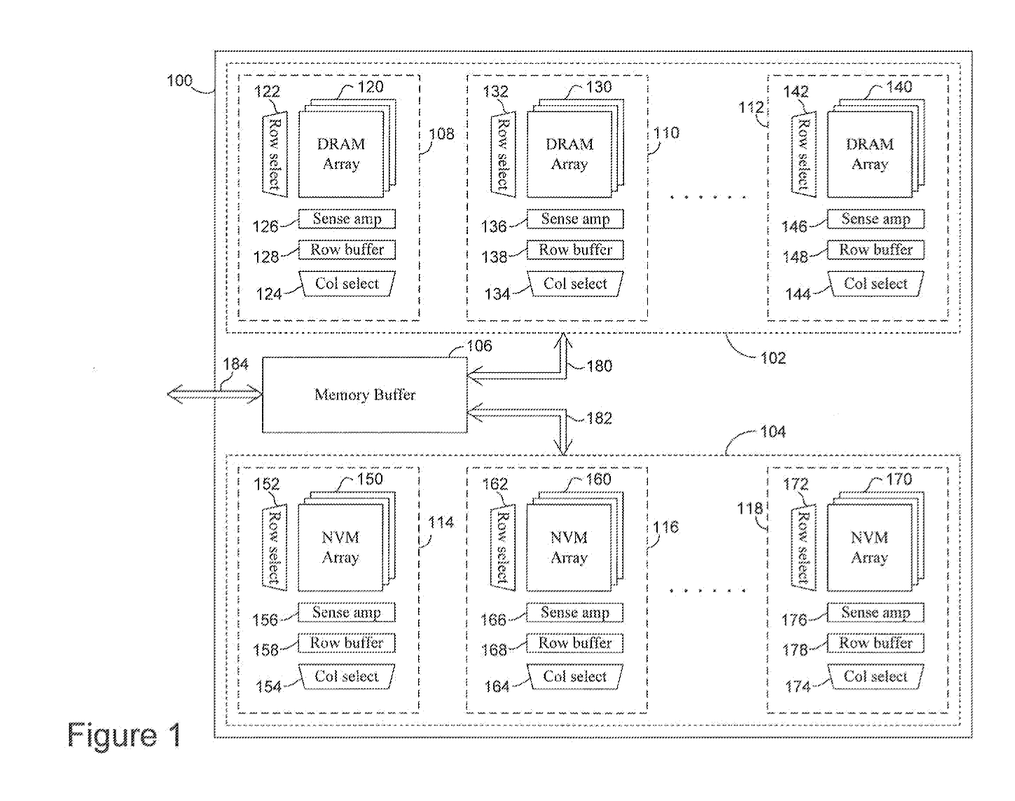

FIG. 1 gives an example of a hybrid memory module 100. The module includes at least two heterogeneous memory devices 102 and 104. A memory buffer 106 is in communication with the memory devices to read data from any one of the memory devices and write the data to any other of the memory devices.

In some examples one of the memory devices comprises DRAM and another comprises non-volatile memory (NVM). In other examples more than one of the memory devices comprise NVM. Each NVM may include single-level cell (SLC) devices or multi-level cell (MLC) devices. Each NVM may be made up of flash memory, phase-change memory (PCM), memristors, magnetoresistive RAM (MRAM), spin-transfer torque RAM (STT-RAM), or other non-volatile elements. In the example shown in FIG. 1, the memory device 102 comprises DRAM and the memory device 104 comprises NVM. In this example the memory device 102 includes several banks of DRAM 108, 110, and 112, and the memory device 104 includes several banks of NVM 114, 116, and 118. In some examples the memory buffer is in communication with the memory devices to read data from two of the memory devices simultaneously, or to write data to two of the memory devices simultaneously, or both, as will be described in more detail presently.

The DRAM bank 108 includes one or more DRAM arrays 120, row and column selectors 122 and 124, sense amplifiers 126, and a row buffer 128. Similarly, the bank 110 includes one or more DRAM arrays 130, row and column selectors 132 and 134, sense amplifiers 136, and a row buffer 138, and the bank 112 includes one or more DRAM arrays 140, row and column selectors 142 and 144, sense amplifiers 146, and a row buffer 148.

The NVM bank 114 includes one or more NVM arrays 150, row and column selectors 152 and 154, sense amplifiers 156, and a row buffer 158. Similarly, the bank 116 includes one or more NVM arrays 160, row and column selectors 162 and 164, sense amplifiers 166, and a row buffer 168, and the bank 118 includes one or more NVM arrays 170, row and column selectors 172 and 174, sense amplifiers 176, and a row buffer 178.

The DRAM bank 102 communicates with the memory buffer 106 through a bus 180. The NVM bank 104 communicates with the memory buffer 106 through a bus 182. The memory bank 106 in turn communicates with a memory controller (not shown) through a bus 184. Other heterogeneous memory modules, and other memory modules that comprise only one kind of memory, may also communicate with the memory controller through the bus 184 or through another communication medium.

In this example the module 100 is shown with one memory buffer. if desired, one or more additional memory buffers may be included.

One (or more) of the DRAM ranks may be used as a cache. This may be a direct-mapped cache in which a data block can only be presented in one location in the cache.

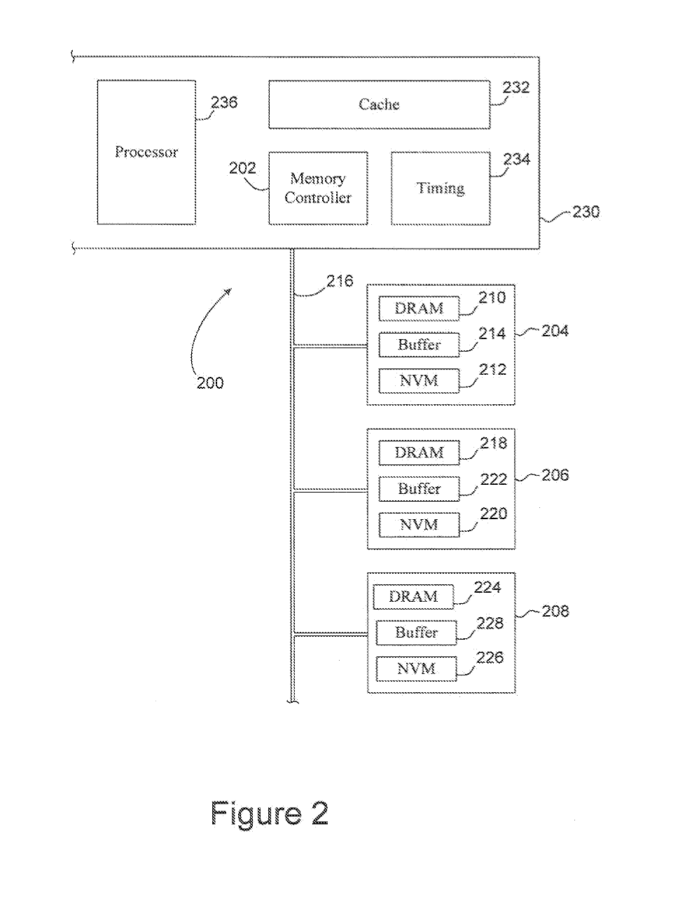

An example of a hybrid memory system 200 is shown in FIG. 2. The system includes a memory controller 202 and one or more hybrid memory modules 204 and 206. This example also includes a third hybrid memory module 208. Other examples may include more than three hybrid memory modules. Each hybrid memory module includes at least two heterogeneous memory devices and a memory buffer. The module 204 includes heterogeneous memory devices 210 and 212, which in this example are DRAM and NVM modules respectively, and a memory buffer 214. The memory buffer 214 is in communication with the memory controller 202, for example through a bus 216, to migrate data between various ones of the memory devices in the module 204.

Similarly, the module 206 includes heterogeneous memory devices 218 and 220, which in this example also are DRAM and NVM modules respectively, and a memory buffer 222. The memory buffer 222 is in communication with the memory controller 202 through the bus 216 or some other communication medium as may be convenient. The module 208 includes heterogeneous memory devices 224 and 226, which as in the other modules in this example are DRAM and NVM respectively, and a memory buffer 228. The memory buffer 228 is in communication with the memory controller 202 through the bus 216 or other communication medium as desired.

The memory controller 202 may reside in a computer system 230. The computer system 230 may comprise a chip multiprocessor (CMP) or other kind of computer system. The computer system 230 includes a cache 232, a timing circuit 234, and a processor 236. Other computer systems may include other devices in addition to or instead of these. The memory controller may be a discrete component, as in this example, or its functions may be performed by a processor such as the processor 236 or other suitable device, either hardwired or under software control.

The memory controller 202 supports migration of data between the heterogeneous memory devices within any one of the modules 204, 206, or 208. A “migrate data” command is included, and the memory controller issues this command to instruct one of the memory buffers to migrate data between memory devices within a module, and from then on the migration is carried out entirely by the memory buffer within the module. This avoids consuming memory channel bandwidth. In addition, the memory controller uses timing information of the data migration to optimally use memory channel bandwidth.

To determine where a piece of data is stored, an on-chip tag/metadata block may be maintained in the cache 232 and consulted to indicate whether any given item of data is stored in one Of the two heterogeneous memory devices. For example, this block may be used to indicate whether a given item of data is stored in the relatively faster of the two devices.

When the memory controller 202 issues a migrate command, it uses the slow device block address of the data to be promoted. The memory buffer calculates the address in the fast device of the data to be demoted. In a more general example, the memory buffer uses a specific cache replacement policy in the fast device to calculate the block frame of the data to be demoted.

Assuming no direct connection between the heterogeneous memory devices in a module, a migration consists of as many as four read-write operations:
(a) Read data to be “promoted”, for example from a relatively slow memory device such as NVM to a relatively fast memory device such as DRAM, into the memory buffer from the slow device.
(b) Read data to be “demoted” into the buffer from the fast device. This need not be done if the data is “clean”, that is, has not been updated subsequent to having been placed in the fast device and the fait device was being used as a cache for the data.
(c) Write the promoted data from the memory buffer into the block frame in the fast device that was occupied by the demoted data.
(d) Write the demoted data into its home location in the slow device. This need not be done if the data is “clean” and if the faster memory device was being used as a cache for the data.

The data to be promoted, and the data to be demoted, can be read into the memory buffer in temporally-parallel operations. Similarly, the data to be promoted and the data to be demoted can be written from the memory buffer to their new locations in parallel. Also, because the migration of data does not consume any memory-channel bandwidth, other operations can be carried out at the same time by the memory controller. For example, during a migration operation the memory controller could access one or more other banks of any of the devices in the memory system.

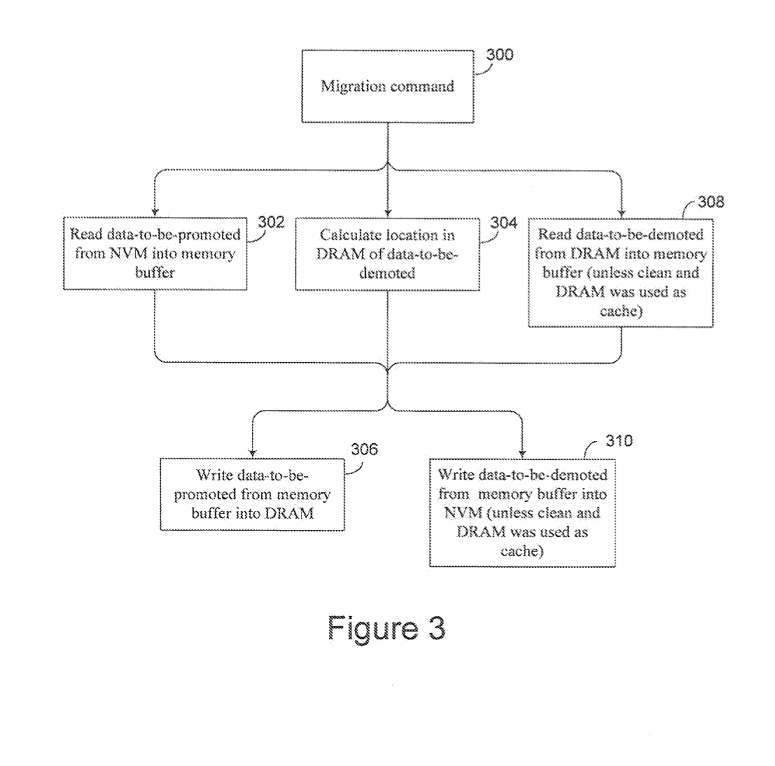

FIG. 3 provides an example of a method of operating a hybrid memory system. The method includes transmitting to a memory buffer a command to migrate an item of data from a first one of at least two heterogeneous memory devices to a second one of the heterogeneous memory devices (300), reading the item of data from the first one of the memory devices into the memory buffer (302), determining a location in the second one of the memory devices into which to write the item of data (304), and writing the item of data from the memory buffer into the second one of the memory devices at the determined location (306). In FIG. 3 the first one of the memory devices is presented as a relatively-slow NVM and the second as a relatively-fast DRAM, but as has been discussed the method is equally applicable to other kinds of memory devices.

Some examples include reading any data already in the second one of the memory devices at the determined location into the memory buffer (308) and writing that data from the memory buffer into the first one of the memory devices (310). If the data. is clean. (unchanged since having been written into the second device) and the second device was being used as a cache for the data, these steps may be omitted.

As shown pictorially in FIG. 3, the steps of reading from the first and second ones of the memory devices may be carried out in parallel—that is, partly or completely overlapped in time. Similarly, the steps of writing to the first and second ones of the memory devices may be carried out in parallel. Also, the step of calculating the location of the data to be demoted may be carried out in parallel with one or both of the steps of reading the data.

The hybrid memory module as described above provides heterogeneous commodity Memory devices within a single module. Data may be migrated between the heterogeneous memory devices without consuming any memory channel bandwidth.

We claim:

1. A hybrid memory module comprising:
at least two heterogeneous memory devices; and
a memory buffer in communication with the memory devices to read data from any one of the memory devices and write the data to any other of the memory devices.

2. The module of claim 1 wherein at least one of the memory devices comprises non-volatile memory (NVM).

3. The module of claim 1 wherein at least one of the memory devices is selected from among single-level cell (SLC) memory devices and multi-level cell (MLC) memory devices.

4. The module of claim 1 wherein at least one of the memory devices is selected from among dynamic random-access memory (DRAM), flash memory, phase-change memory (PCM), memristor, magnetoresistive RAM (MRAM), and spin-transfer torque RAM (STT-RAM).

5. The module of claim I wherein one of the memory devices comprises at least one bank of dynamic random-access memory (DRAM) and another of the memory devices comprises at least one bank of non-volatile memory (NVM).

6. The module of claim 1 wherein the memory buffer is in communication with the memory devices to read data from two of the memory devices simultaneously.

7. The module of claim 1 wherein the memory buffer is in communication with the memory devices to write data to two of the memory devices simultaneously.

8. A hybrid memory system comprising:
a Memory controller; and
at least one hybrid memory module, each module comprising at least two heterogeneous memory devices and a memory buffer, the memory buffer in each module communication with the memory controller to migrate data between various ones of the memory devices in that module.

9. The system of claim 8 wherein the memory devices in each module are selected from among dynamic random-access memory (DRAM) and non-volatile memory (NVM).

10. The system of claim 9 wherein at least one of the memory devices in each module is selected from among single-level cell (SLC) memory devices and multi-level cell (MLC) memory devices.

11. The system of claim 9 wherein at least one of the memory devices in each module is selected from among flash memory, phase-change memory (PCM), memristor, magnetoresistive RAM (MRAM), and spin-transfer torque RAM (STT-RAM).

12. The system of claim 8 wherein one of the memory devices in one of the hybrid memory modules comprises at least one bank of dynamic random-access memory (DRAM) and another of the memory devices in that module comprises at least one bank of non-volatile memory (NVM).

13. The system of claim 8 wherein the memory buffer is in communication with the memory devices to read data-to-be-promoted from one of the memory devices and data-to-be-demoted from another of the memory devices simultaneously.

14. The system of claim 8 wherein the memory buffer is in communication with the memory devices to write data-to-be-promoted to one of the memory devices and data-to-be-demoted to another of the memory devices simultaneously.

15. A method of operating a hybrid memory system, the method comprising:
transmitting to a memory buffer a command to migrate an item of data from a first one of at least two heterogeneous memory devices to a second one of the heterogeneous memory devices;
reading the item of data from the first one of the memory devices into the memory buffer;
determining a location in the second one of the memory devices into which to Write the item of data; and
writing the item of data from the memory buffer into the second one of the memory devices at the determined location.

16. The method of claim 15 and further comprising:
reading any data already in the second one of the memory devices at the determined location into the memory buffer; and
writing that data from the memory buffer into the first one of the memory devices.

17. The method of claim 16 wherein the steps of reading from the first and second ones of the memory devices are carried out simultaneously.

18. The method of claim 16 wherein the steps of writing to the first and second ones of the memory devices are carried out simultaneously.

19. The method of claim 15 and further comprising:
determining whether any data already in the second one of the memory devices at the determined location has been changed since any previous write of that data to another location, and if so, reading that data into the memory buffer; and
writing that data from the memory buffer into the first one of the memory devices.
